(19) United States
(12) Patent Application Publication
(10) Pub. No.: US 2010/0091458 A1
(43) Pub. Date: Apr. 15, 2010

(54) ELECTRONICS CHASSIS WITH ANGLED CARD CAGE

(76) Inventors: David W. Mosier, JR., Raleigh, NC (US); Rodney G. Bame, Raleigh, NC (US)

Correspondence Address: COATS & BENNETT, PLLC, 1400 Crescent Green, Suite 300, Cary, NC, 27518, US

(21) Appl. No.: 12/550,826

(22) Filed: Aug. 31, 2009

Related U.S. Application Data
(60) Provisional application No. 61/105,453, filed on Oct. 15, 2008.

(51) Int. Cl. H05K 7/20

(52) U.S. Cl. 361/695

(57) ABSTRACT

A configuration for a computer system chassis that allows for more efficient cooling airflow. The card cage is deliberately tilted relative to the remainder of the chassis at a non-orthogonal angle, such as approximately 5°-10°, while otherwise maintaining the standard vertical and lateral dimensions and orientation of the chassis's cabinet. This results in an increase in the size of the inlet air opening and the exhaust air opening, and a corresponding decrease in the airflow resistance in the system. Other aspects and methods are also disclosed.

This application claims the benefit of U.S. Provisional Application No. 61/105,453, filed 15 Oct. 2008, the disclosure of which is incorporated herein by reference.

### BACKGROUND

The present invention relates to electronics system chassis configurations, particularly those that use forced air movement to cool the components therein.

Many complex electronics systems, such as computer and telecommunications systems, rely on modules that are secured in standardized racking systems. The height and other dimensions of these modules must comply with pre-determined specifications so that modules provided by various manufacturers may be readily used in combination. Example standards are, but are not limited to, VME, VME 64, cPCI, ATCA, AMC, ARINC, and MicroTCA, with these standards defined by several organizations including ANSI, PICMG, IEEE, VITA, and other standards organizations. Further, because these modules contain electronics that generate heat, suitable cooling airflow must be provided. It is common for these standards to require that the module cooling air inlets and outlets be located only on the front and rear of the modules. This is because the modules are typically stacked together in the rack, and the presence of another module immediately above or below should not prevent the module from getting the required amount of cooling air if the air inlets and outlets are positioned in these locations. Thus, it is common for a chassis module to intake air in the lower front of the chassis and exhaust air out the upper rear of the chassis.

Many modules are designed to use replaceable electronics circuit boards, sometimes referred to as Line Replaceable Units (LRUs). An LRU is a modular circuit board that is designed to plug into a chassis and connect electrically to other LRU boards via a backplane in the chassis. Typically, a given chassis is designed to hold multiple LRUs in a card cage. In the prior art, the card cage is configured for the LRUs to be inserted into and removed from the card cage horizontally when the modules are mounted in a vertical rack. Thus, the LRUs are inserted into, and removed from, the card cage horizontally. However, some chassis have card cages that allow for the LRUs to be inserted into and removed from either the top or the side of the chassis. Regardless, the card cage is oriented horizontally when mounted in the vertical rack. An array of cooling fans is typically disposed immediately above and/or immediately below the card cage. This array of fans typically follows the card cage in that the array is disposed horizontally, with the fans typically blowing air vertically. Alternatively, the fans located elsewhere and/or may blow the cooling air horizontally front-to-back or back-to-front, rather than vertically, such as in some military or ATR chassis modules.

While the above arrangements have proven satisfactory for some situations, they have proven unsatisfactory for others, particularly for high heat load situations. As such, there remains a need for alternative approaches to cooling electronics system chassis, advantageously ones that allow for more efficient cooling.

### SUMMARY

In one exemplary embodiment, the present invention is embodied in an electronics enclosure. The enclosure advantageously comprises a first face including at least one air inlet; a second face having at least one air exhaust; and a card cage having a plurality of vertical card slots laterally offset from one another for receiving a plurality of electronic cards. Each of the plurality of card slots have respective longitudinal axes that are substantially parallel, and these longitudinal axes extend away from one of the first and second faces at a non-orthogonal angle so that the card cage is tilted with respect thereto. In some embodiments, the relevant face is the front face of the enclosure, and the angle is a downward angle (front-to-back) so that the front of the card cage is higher than the rear of the card cage. The angle may be 1° to approximately 45°, and advantageously is between about 5° and about 35°. A first inlet plenum is operatively disposed between the air inlet and the card cage and has a cross-section which becomes smaller as the distance increases from the air inlet. A second exhaust plenum is operatively disposed between the card cage and the air exhaust and has a cross-section which becomes larger as the distance decreases towards the air exhaust. At least one fan is operative to force air to flow along an airflow pathway that extends from the air inlet into the first plenum, through the card cage, into the second plenum, and out the air exhaust.

In another illustrative embodiment, the present invention is embodied in an electronics chassis that includes a housing having a first face, a second face, a top, and a bottom. The first face has at least one an air inlet. The second face is oriented generally opposite the first face and has at least one air outlet. The bottom is substantially planar and disposed between the first and second face. A card cage is disposed in the housing, the card cage having a plurality of card slots for receiving corresponding removable electronics cards; the card cage having a longitudinal axis aligned with the card slots and forming an acute angle with respect to the bottom. An inlet plenum is operatively disposed between the card cage and the air inlet; the inlet plenum has a cross-section which becomes smaller as the distance increases from the air inlet. An outlet plenum is operatively disposed between card cage and the air outlet; the outlet plenum has a cross-section which becomes larger as the distance decreases towards the air exhaust.

In another embodiment, the present invention provides a method of removing heat from an electronics chassis. The method comprises: routing incoming cooling air though one of a front and a rear of an outer cabinet; forcing said air through an inlet plenum to a card cage having a plurality of card slots for receiving corresponding removable electronics cards; the card cage disposed in the outer cabinet at a non-orthogonal angle relative to the one of the front and rear; exhausting the air from the card cage into an outlet plenum and then out an outlet in the other of the front and rear; wherein the inlet plenum has a cross-section that decreases toward the one of the front and rear; and wherein the outlet plenum has a cross-section that increases toward the one of the front and rear.

Other aspects of various embodiments of the inventive apparatus and related methods are also disclosed in the following description. The various aspects may be used alone or in any combination, as is desired.

### BRIEF DESCRIPTION OF THE DRAWINGS

FIG. 1 shows an electronics module chassis mounted in a mounting rack.

FIG. 2 shows a cross-sectional view of an electronics enclosure according to one embodiment of the present invention.

FIG. 3 shows a cross-sectional view of the electronics module chassis for FIG. 2 for another illustrative embodiment.

### DETAILED DESCRIPTION

The present invention relates generally to an improved configuration for a computer system enclosure that allows for more efficient cooling airflow. According to the present invention, the card cage is deliberately tilted relative to the remainder of the chassis, while otherwise maintaining the standard vertical and lateral dimensions and orientation of the outer cabinet. The result is an increase in the size of the inlet air opening and the exhaust air opening, and a corresponding decrease in the airflow resistance in the system. This arrangement allows for better airflow through the unit, thereby increasing cooling efficiency.

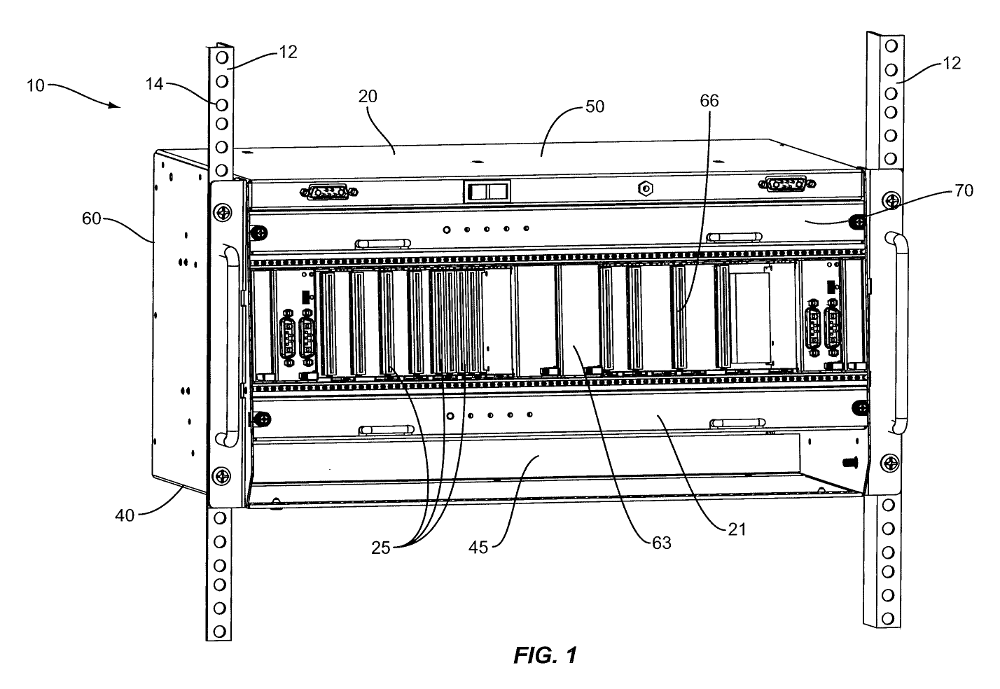

As illustrated in FIG. 1, an exemplary electronics enclosure according to one embodiment of the present invention, generally indicated at 20, is intended to be mounted in a conventional rack 10, a portion of which is shown in FIG. 1. The rack 10 typically includes left and right rails or flanges 12, with suitable mounting holes 14 located at appropriate intervals.

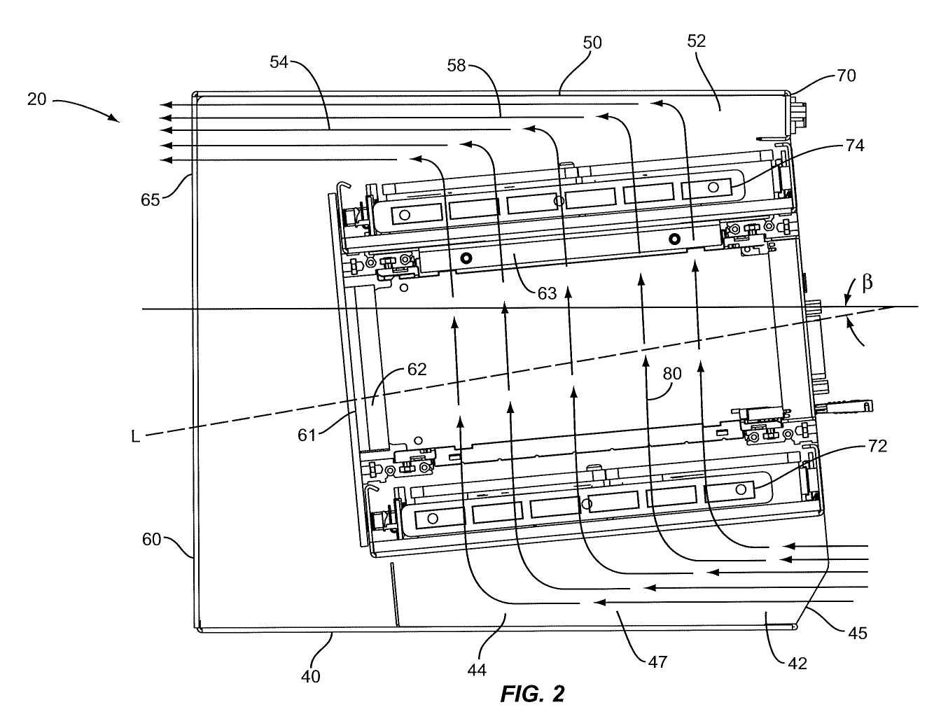

FIG. 2 shows the electronics enclosure 20 of FIG. 1, in the form of an electronics module chassis, having a top 50, a bottom 40, a rear 60, and a front 70. The top 50 and bottom 40 are typically parallel to each other, and the rear 60 is typically orthogonal to the top 50 and bottom 40. A card cage 63 is mounted so as to extend inward from the front 70 into the enclosure 20 and includes a plurality of card-receiving connectors 62, as is conventional. Further, as is customary, the rear of the card cage 63 includes an inter-connection backplane 61 with suitable connectors 62 for electrically connecting Line Replaceable Units (LRU). However, unlike in the prior art, the card cage 63 is mounted at a non-orthogonal downward angle D (front-to-back) relative to the chassis bottom 40 so that the front of the card cage is higher than the rear of the card cage. That is, the card-receiving connectors 62, rather than running horizontally, are angled downward front-to-back so that the longitudinal axis L of the card cage 63 is not parallel to the top 50 and bottom 40 of the enclosure 20.

Cooling fans 72 may be disposed below the card cage 63, and are typically arranged in an orderly array. Other cooling fans 74 may be disposed above the card cage 63, and are also typically arranged in an orderly array. Each of the cooling fan arrays may advantageously be insertable from the front 70 of the module, and advantageously be hot-swappable and self identifying to any control electronics. An inlet plenum 47 is disposed below the card cage 63 and extends from the lower cooling fans 72 to an air inlet 45 on the front 70. If desired, an air filter (not shown) may extend below the fans 72 and in the inlet plenum 45. Further, the inlet plenum 27 may advantageously be isolated from the rest of the module's interior (other than the card cage) by suitable baffles and/or interior walls/flanges. A corresponding outlet plenum 58 extends from the upper cooling fans 74 to an air exhaust outlet 65 on the rear 60. For reference, the airflow path through the module is shown at 80.

As can be seen, the orientation of the card cage 63 gives the air inlet plenum 47 a cross-section that diminishes front-to-back. That is, the front portion 42 of the inlet plenum 47 has a greater cross-section than the rear portion 44 of the inlet plenum 47. In addition, the fans 72 are angled relative to the average direction of travel of the inlet air in the inlet plenum 27, such that the inlet air arrives at the fans 72 at an angle less than 90°. The amount of change in cross-section depends on the amount of angulation of the card cage 63. The present invention contemplates that the angle β between card cage 63 and horizontal is between 1° and 45°, with values of 5° to 35° believed advantageous, and values of approximately 5° to approximately 10° being advantageous for most applications. It should be noted that the angulation should not be such as to cause the card cage 63 to extend outside the allowed dimensions of the module outer cabinet. Further, it should be kept in mind that as angle β increases, the cross-sectional area of the inlet plenum 47 in the rear portion 44 thereof will decrease. Care should be taken to ensure that the fans 72 receive sufficient air to properly function.

The angled orientation of the card cage 63 also causes the outlet plenum 58 to have a variable cross-section, with the cross-section increasing in a front-to-back direction. Thus, the front portion 52 of the outlet plenum 58 has a smaller cross-section than the rear portion 54 of the outlet plenum 58. Also, the air leaving the upper fans 74 is slightly angled rearwardly, meaning that a full 90° turn of the exhaust air is not required to reach the exhaust outlet 65.

Angling the internal card cage 63 allows the inlet 45 and exhaust outlet 65, and the corresponding inlet plenum front portion 42 and outlet plenum rear portion 54, to be increased in size without changing the vertical dimensions of the enclosure 20. This increased size allows for easier airflow through the inlet 45 and exhaust outlet 65. Likewise, the relative angle between the fans 72, 74 and the inlet/outlet 45, 65 is decreased, allowing the fans 72, 74 to operate more efficiently. The net effect of the card cage 63 angulation is to reduce the backpressure of the air as is flows along the airflow path 80 through the unit. As such, more air can travel through the unit, and therefore heat can be more readily discharged from the module. In addition, the non-orthogonal downward angle of the card cage 63 allows gravity to assist in retaining the LRUs in the card cage 63, which may be advantageous when the cards 26 are not locked in position.

While the previous embodiment found it advantageous to position card cage 63 within module chassis 20 with a downward angle, other embodiments of the present invention may find it advantageous for card cage 63 to be positioned within module chassis 20 with a non-orthogonal upward angle, while still maintaining the relative cross-sections described above, such that the air inlet can be positioned in the front upper portion of the chassis. Additionally, it should be understood that a non-orthogonal angle is any angle which is not 0°, 90°, or any multiple of 90°, such at 180°, 270°, 360°, and so on.

In some embodiments, the module chassis 20 may include fans in other locations. For example, some embodiments may have fans vertically oriented (blowing horizontally) and disposed in the upstream portion of the inlet plenum 47 near the inlet 45, rather than immediately above and below the card cage 63. In other embodiments, these fans may be disposed at other angles, such as angled upward by, for example, 20°. In still other embodiments, the fans may be located in a downstream position, such as in the outlet plenum 58. It should also be noted that the term “fan” should be broadly construed to include any rotating powered air moving device, such as axial blowing fans and centrifugal blowing devices sometimes known as “blowers”.

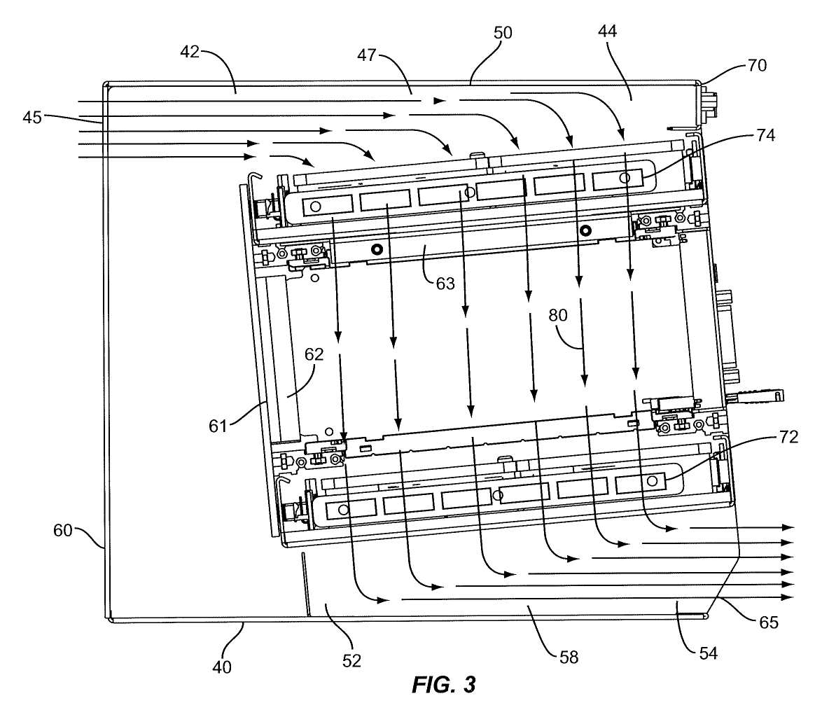

In another embodiment of the present invention the airflow 80 shown in FIG. 2 is reversed, as seen in FIG. 3. In contrast to the embodiment illustrated in FIG. 2, the inlet plenum 47 of FIG. 3 is disposed above the card cage 63 and extends from the upper cooling fans 74 to an air inlet 45 on the rear 60. The corresponding outlet plenum 58 extends from the lower cooling fans 72 to an air exhaust outlet 65 on the front 70. As can be appreciated, the fans 72,74 should operate in a reverse direction compared to those in FIG. 2. However, as with the embodiment shown in FIG. 2, inlet plenum 47 has a cross-section which becomes smaller as the distance increases away from air inlet 45 and outlet plenum 58 has a cross-section which becomes larger as the distance decreases towards exhaust 65.

Further, the enclosure 20 may include a suitable power supply (not shown), such as an AC to DC power supply which may or may not have its own cooling system and on/off switch. Such a power supply may be located as desired, such as between the card cage 63 and the rear 60.

Further still, the discussion above has been in the context of a configuration where cards are inserted and removed from the card cage 63 from the front 70. However, embodiments of the present invention may alternatively be of configurations where cards are inserted and removed from the card cage 63 from the top 50, rear 60, or the sides of the chassis 20.

The present invention may be carried out in other specific ways than those herein set forth without departing from the scope and essential characteristics of the invention. Further, the various aspects of the disclosed device and method may be used alone or in any combination, as is desired. The disclosed embodiments are, therefore, to be considered in all respects as illustrative and not restrictive, and all changes coming within the meaning and equivalency range of the appended claims are intended to be embraced therein.

What is claimed is:

1. An electronics enclosure comprising:
a first face including at least one air inlet;
a second face having at least one air exhaust;
a card cage having a plurality of vertical card slots laterally offset from one another for receiving a plurality of electronic cards; wherein each of the plurality of card slots have respective longitudinal axes that are substantially parallel; wherein the longitudinal axes extend away from one of said first and second faces at a non-orthogonal angle so that the card cage is tilted with respect thereto;
a first plenum disposed operatively between the air inlet and the card cage;
the first plenum having a cross-section which becomes smaller as the distance increases from the air inlet;
a second plenum disposed operatively between the card cage and the air exhaust; the second plenum having a cross-section which becomes larger as the distance decreases towards the air exhaust;
at least one fan operative to force air to flow along an airflow pathway that extends from the air inlet into the first plenum, through the card cage, into the second plenum, and out the air exhaust.

2. The electronics enclosure of claim 1 wherein the longitudinal axes extend away from one of said first face at a downward angle.

3. The electronics enclosure of claim 1 wherein the angle is between 1° and 45°.

4. The electronics enclosure of claim 3 wherein the angle is between approximately 3° and approximately 10°.

5. The electronics enclosure of claim 4 wherein the angle is approximately 5°.

6. The electronics enclosure of claim 1 wherein said fan is disposed downstream of the inlet plenum and upstream of the card cage.

7. The electronics enclosure of claim 6 wherein the fan is a first fan, and further comprising a second fan disposed downstream of the card cage and operative to assist the first fan in forcing the air to flow along the airflow pathway.

8. The electronics enclosure of claim 1 wherein the first face including at least one air inlet is on a front portion of the electronics enclosure and the at least one air inlet is positioned in the lower portion thereof.

9. The electronics enclosure of claim 1 wherein the first face is a rear of the enclosure and the inlet plenum is disposed above the card cage.

10. An electronics chassis, comprising:
a housing having a first face, a second face, a top, and a bottom;
the first face having at least one an air inlet;
the second face oriented generally opposite the first face and having at least one air outlet;
the bottom being substantially planar and disposed between the first and second face;
a card cage disposed in the housing, the card cage having a plurality of card slots for receiving corresponding removable electronics cards; the card cage having a longitudinal axis aligned with the card slots and forming an acute angle with respect to the bottom;
an inlet plenum operatively disposed between the card cage and the air inlet; the inlet plenum having a cross-section which becomes smaller as the distance increases from the air inlet;
an outlet plenum operatively disposed between card cage and the air outlet; the outlet plenum having a cross-section which becomes larger as the distance decreases towards the air exhaust.

11. The device of claim 10 wherein the angle is between 1° and 45°.

12. A method of removing heat from an electronics chassis, comprising:
routing incoming cooling air though one of a front and a rear of an outer cabinet;
forcing said air through an inlet plenum to a card cage having a plurality of card slots for receiving corresponding removable electronics cards; the card cage disposed in the outer cabinet at a non-orthogonal angle relative to the one of the front and rear;
exhausting the air from the card cage into an outlet plenum and then out an outlet in the other of the front and rear;
wherein the inlet plenum has a cross-section that decreases toward the one of the front and rear; and
wherein the outlet plenum has a cross-section that increases toward the one of the front and rear.

13. The method of claim 12 wherein the angle is between 1° and 45°.

14. The method of claim 12 wherein the one of the front and rear is the front.

15. The method of claim 12 wherein the forcing the air through the inlet plenum to the card cage comprises routing the air though a fan. .
